(19) United States
(12) Patent Application Publication
(10) Pub. No.: US 2015/0061717 A1
(43) Pub. Date: Mar. 5, 2015

(54) TEST CARRIER, DEFECT DETERMINATION APPARATUS, AND DEFECT DETERMINATION METHOD

(71) Applicant: ADVANTEST CORPORATION, Tokyo (JP)

(72) Inventor: Kiyoto Nakamura, Miyagi (JP)

(73) Assignee: ADVANTEST CORPORATION, Tokyo (JP)

(21) Appl. No.: 14/390,607

(22) PCT Filed: May 21, 2013
(86) PCT No.: PCT/JP2013/064077

§ 371 Date: Oct. 3, 2014

(30) Foreign Application Priority Data
May 23, 2012 (JP) 2012-117423

(51) Int. Cl. G01R 31/28; G01R 1/04

(52) U.S. Cl. CPC G01R 31/2853; G01R 1/0491
USPC 324/756.02

(57) ABSTRACT

A test carrier that temporarily accommodates a die includes: a first wiring pattern that electrically connects an external terminal of the test carrier and a TSV of the die; and a second wiring pattern that electrically connects the TSVs.

### TECHNICAL FIELD

The present invention relates to a test carrier on which a die chip is temporarily mounted in order to test an electronic circuit, such as an integrated circuit, of the die chip, and a defect determination apparatus and method that determines whether a TSV of the die chip is defective using the test carrier.

For the designated countries which permit the incorporation by reference, the contents described and/or illustrated in Japanese Patent Application No. 2012-117423 filed on May 23, 2012 are incorporated by reference in the present application as a part of the description and/or drawings of the present application.

### BACKGROUND ART

As a test carrier on which a semiconductor chip in a bare chip state is temporarily mounted, a test carrier has been known in which a semiconductor chip is interposed between a cover and a base under a reduced pressure atmosphere (for example, see Patent Document 1).

A wiring pattern corresponding to an electrode of the semiconductor chip is formed on the cover of the test carrier, and the semiconductor chip is connected to an external testing apparatus through the wiring pattern.

### CITATION LIST

### Patent Document

Patent Document 1: JP H07-264504 A

### DISCLOSURE OF THE INVENTION

### Problem to be Solved by the Invention

The above-mentioned test carrier has the problem that it is impossible to determine whether a through silicon via (TSV) formed in the semiconductor chip is defective.

An object of the invention is to provide a test carrier that can determine whether a TSV is defective and a defect determination apparatus and method using the test carrier.

### Means for Solving Problem

[1] According to the invention, there is provided a test carrier that temporarily accommodates an electronic device, the test carrier comprising: a first wiring pattern that electrically connects an external terminal of the test carrier and one of electrodes which the electronic device has; and a second wiring pattern that electrically connects at least two of the electrodes.

[2] In the above-mentioned invention, the electrodes of the electronic device may include a through electrode that passes through a body of the electronic device.

[3] In the above-mentioned invention, the test carrier may further comprise: a first member that holds the electronic device; and a second member that overlaps the first member so as to cover the electronic device, wherein the external terminal and the first wiring pattern may be provided in the first member, and the second wiring pattern may be provided in the second member.

[4] In the above-mentioned invention, the second member may include: a first film that has a self-adhesive property; and a second film that is interposed between the first film and the electronic device, and the second wiring pattern may be formed on the second film.

[5] In the above-mentioned invention, the second member may have a surface on which an adhesive layer with a self-adhesive property is partially formed, and the second wiring pattern may be formed in a region of the surface of the second member in which the adhesive layer is not formed.

[6] In the above-mentioned invention, the first member may have a surface on which a layer with a self-adhesive property is formed, and the second wiring pattern may be formed on a surface of the second member.

[7] In the above-mentioned invention, the second wiring pattern may include a planar solid pattern that electrically connects all of the through electrodes of the electronic device.

[8] According to the invention, there is provided a defect determination apparatus comprising: a resistance measurement means that measures a resistance value of a conduction path through the external terminal of the above-mentioned test carrier, the conduction path including the through electrode; and a determination means that determines whether the through electrode is defective on the basis of the resistance value.

[9] According to the invention, there is provided a defect determination method comprising: a first step of electrically connecting at least two through electrodes of an electronic device in series to each other and measuring a resistance value of a conduction path including the through electrodes; and a second step of determining whether the through electrode is defective on the basis of the resistance value.

### Effect of the Invention

According to the invention, since the test carrier includes the second wiring pattern that electrically connects the electrodes in series, it is possible to measure the resistance value of the conduction path including the electrodes and to determine whether a TSV is defective.

### BRIEF DESCRIPTION OF DRAWINGS

FIG. 1 is a flowchart illustrating a portion of a device manufacturing process in an embodiment of the invention;

FIG. 2(a) is a plan view illustrating a die to be tested in the embodiment of the invention and FIG. 2(b) is a cross-sectional view taken along the line IIB-IIB of FIG. 2(a);

FIG. 3 is an exploded perspective view illustrating a test carrier in the embodiment of the invention;

FIG. 4 is a cross-sectional view illustrating the test carrier in the embodiment of the invention;

FIG. 5 is an exploded cross-sectional view illustrating the test carrier in the embodiment of the invention;

FIG. 6 is an enlarged view of FIG. 5;

FIG. 7 is an exploded cross-sectional view illustrating a modification of a base member in the embodiment of the invention;

FIG. 8 is an exploded cross-sectional view illustrating another modification of the base member in the embodiment of the invention;

FIG. 9(a) is a cross-sectional view illustrating a modification of a second wiring pattern in the embodiment of the invention and FIG. 9(b) is a plan view illustrating the modification of the second wiring pattern;

FIG. 10 is an exploded cross-sectional view illustrating a modification of the test carrier in the embodiment of the invention;

FIG. 11 is an exploded cross-sectional view illustrating another modification of the test carrier in the embodiment of the invention;

FIG. 12 is a block diagram illustrating the structure of a testing apparatus in the embodiment of the invention; and

FIG. 13 is a flowchart illustrating a TSV defect determination method in the embodiment of the invention.

### MODE(S) FOR CARRYING OUT THE INVENTION

Hereinafter, an embodiment of the invention will be described with reference to the drawings.

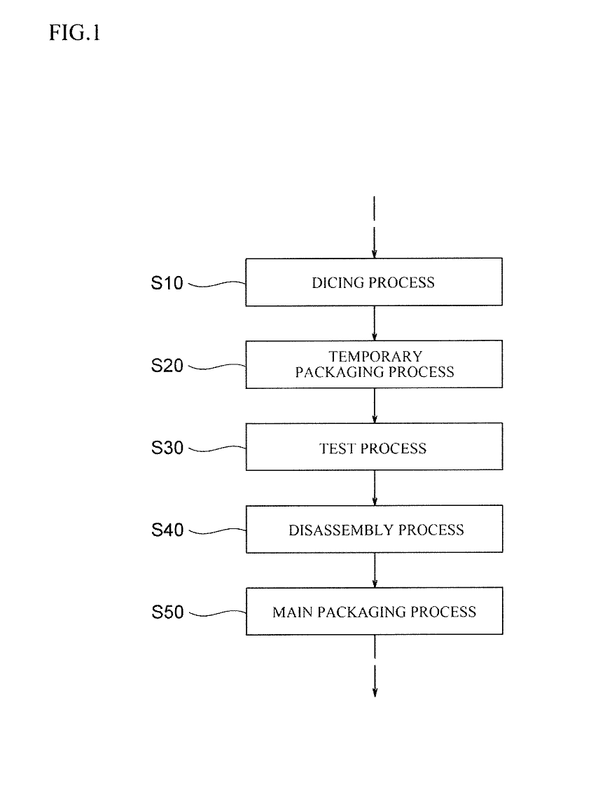

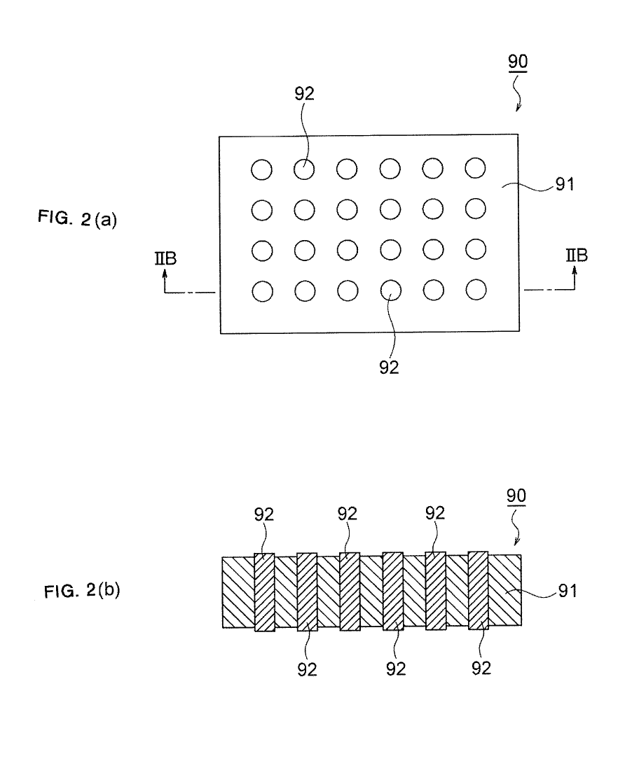

FIG. 1 is a flowchart illustrating a portion of a device manufacturing process in the present embodiment. FIG. 2(a) is a plan view illustrating a die to be tested and FIG. 2(b) is a cross-sectional view illustrating the die.

In the present embodiment, an electronic circuit which is incorporated into a die 90 is tested after a semiconductor wafer is diced (after Step S10 in FIG. 1) and before final packaging is performed (before Step S50) (Steps S20 to S40).

In the present embodiment, first, the die 90 is temporarily mounted on a test carrier 10 by a carrier assembly apparatus (not illustrated) (Step S20). Then, the die 90 is electrically connected to a testing apparatus (not illustrated) via the test carrier 10, and the electrical characteristics of an electronic circuit formed in the die 90 are tested (Step S30). After the test ends, the die 90 is taken out of the test carrier 10 (Step S40) and main packaging is performed on the die 90. In this way, a device is completed as a final product (Step S50).

As illustrated in FIGS. 2(a) and 2(b), the die 90 which is a test target in the present embodiment includes a plurality of through silicon vias 92 (TSVs: hereinafter, simply referred to as TSVs) that pass through a main body 91 of the die 90. In Step S30, it is determined whether the TSV 92 is defective. FIG. 2 illustrates only 24 TSVs 92 that are arranged in a matrix. However, in practice, a plurality of TSVs 92 are formed in the die 90 in any array, and the number or arrangement of TSVs 92 is not particularly limited.

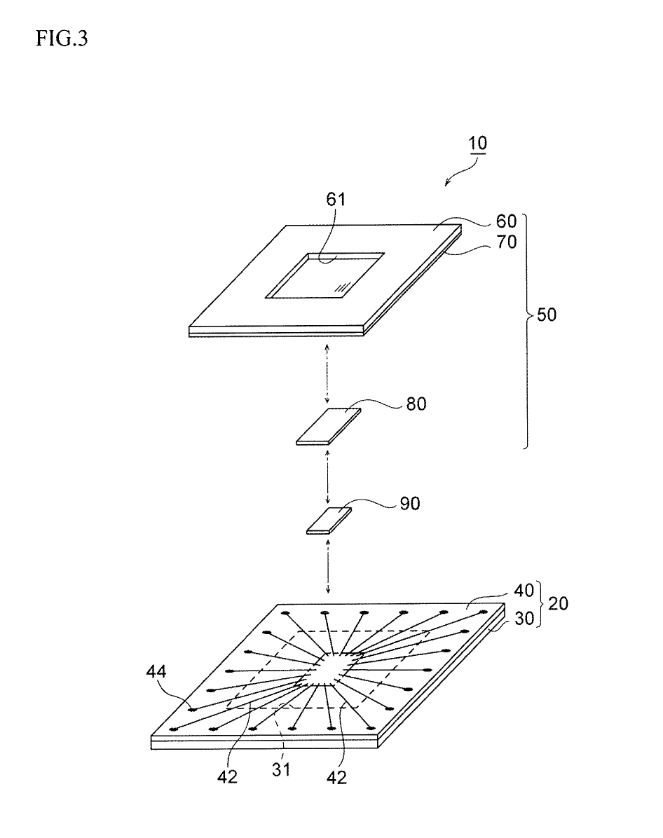

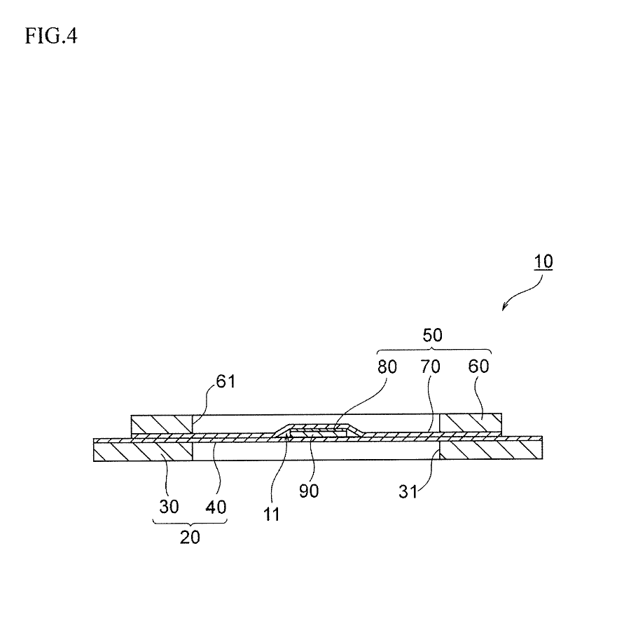

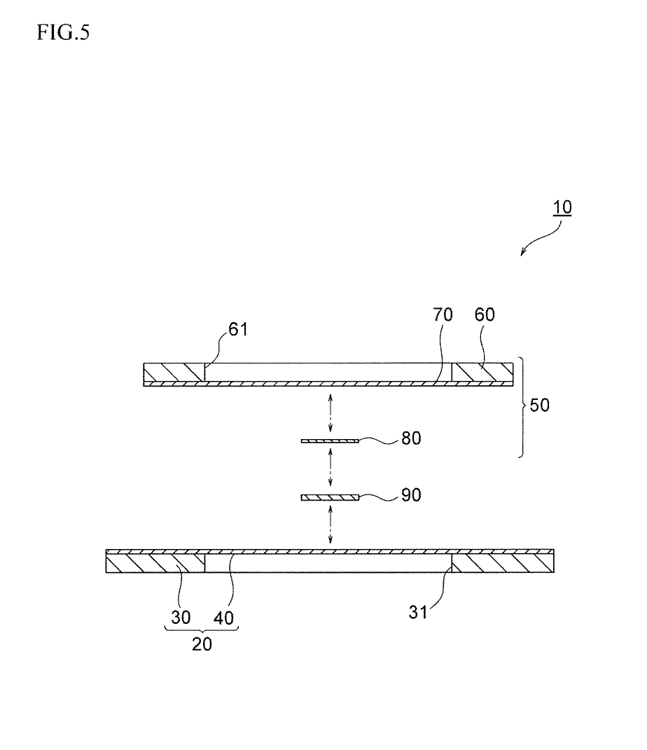

Next, first, the structure of the test carrier 10 on which the die 90 is temporarily mounted (temporarily packaged) in the present embodiment will be described with reference to FIGS. 3 to 11.

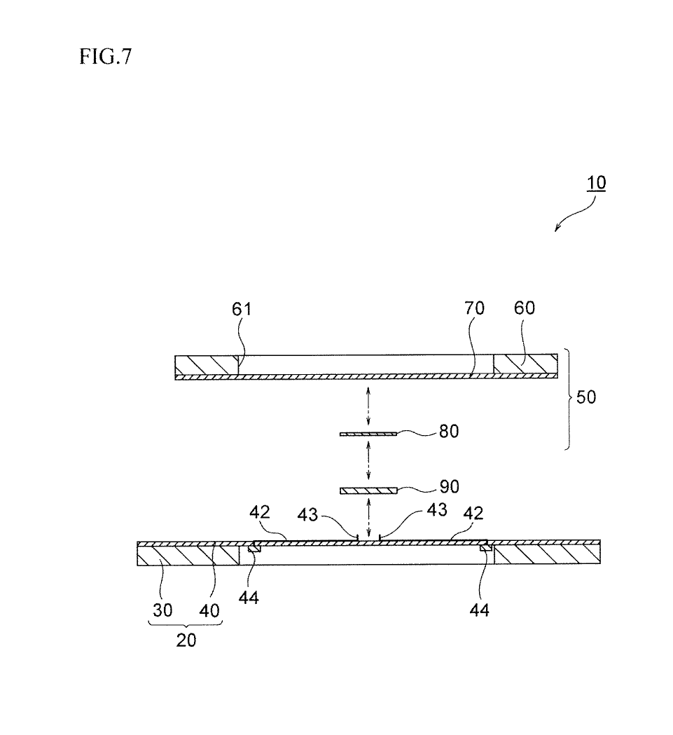

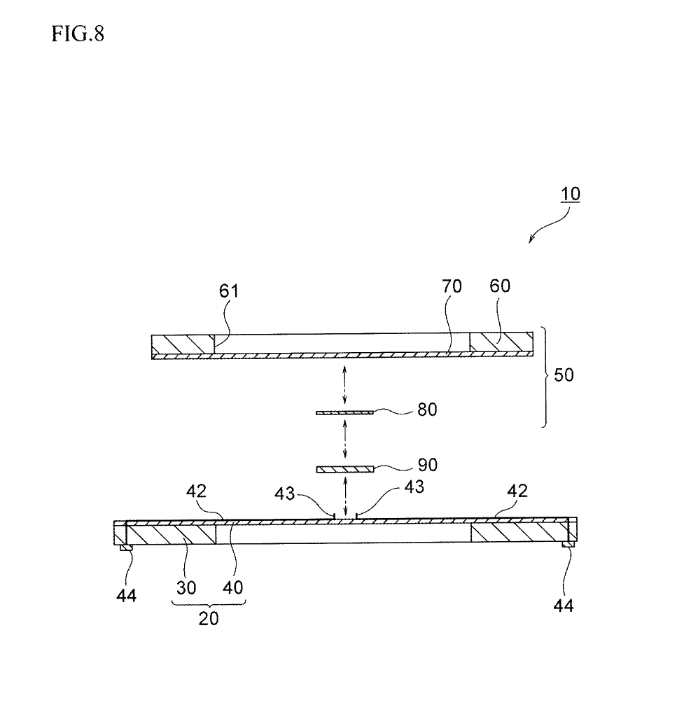

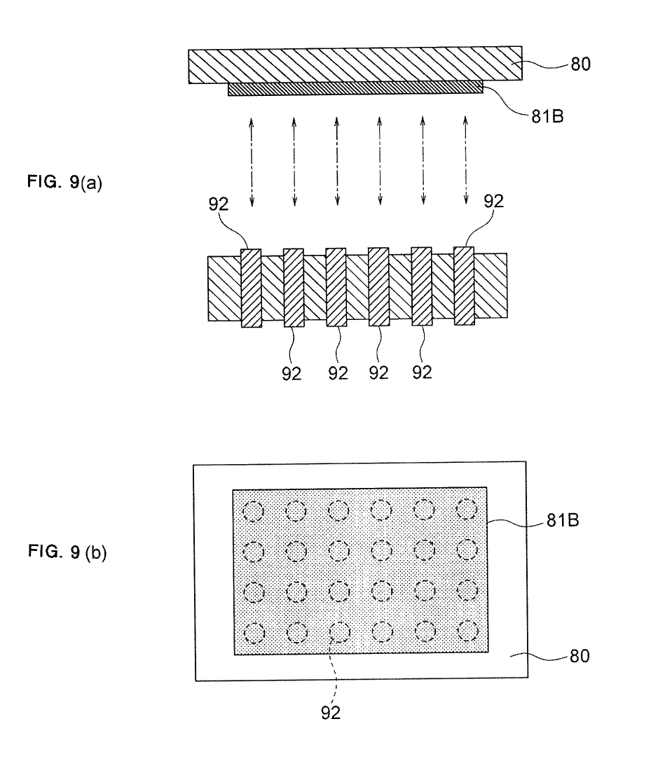

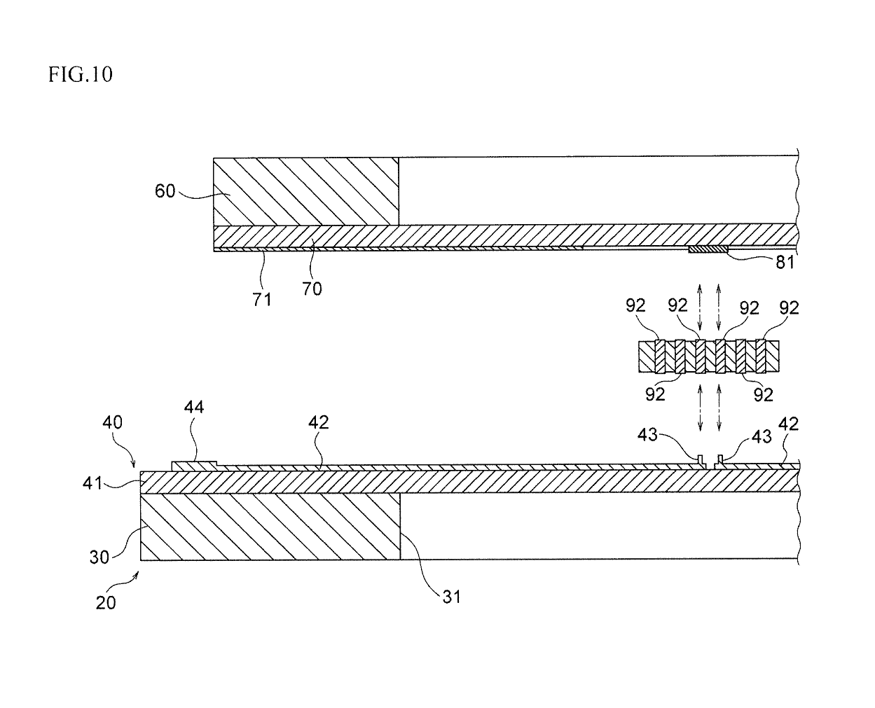

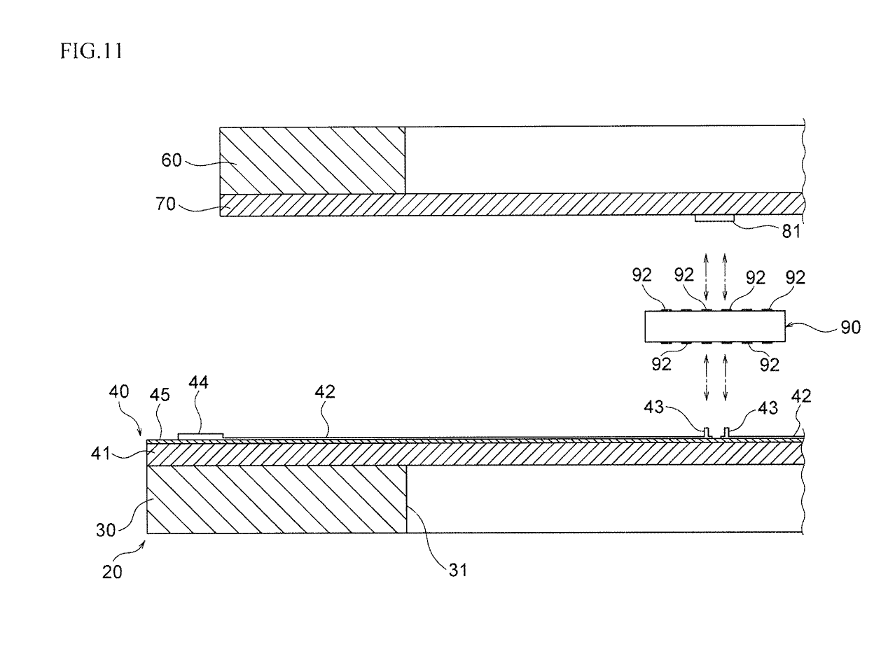

FIGS. 3 to 6 are diagrams illustrating the test carrier in the present embodiment. FIGS. 7 and 8 are diagrams illustrating modifications of a base member in the present embodiment. FIGS. 9(a) and 9(b) are diagrams illustrating a modification of a second wiring pattern. FIGS. 10 and 11 are diagrams illustrating modifications of the test carrier.

As illustrated in FIGS. 3 to 6, the test carrier 10 in the present embodiment includes: a base member 20 on which the die 90 is placed; and a cover member 50 which overlaps the base member 20 so as to cover the die 90. The die 90 is interposed between the base member 20 and the cover member 50 so that the test carrier 10 holds the die 90. The die 90 in the present embodiment corresponds to an example of an electronic device in the invention.

The base member 20 includes a base frame 30 and a base film 40. The base member 20 in the present embodiment corresponds to an example of a first member in the invention.

The base frame 30 is a rigid board that has high rigidity (has higher rigidity than at least the base film 40) and has an opening 31 formed at the center thereof. As the material forming the base frame 30, a polyimide resin, a polyamide-imide resin, a glass epoxy resin, ceramics, or glass is exemplified.

The base film 40 is a flexible film and is stuck to the entire surface of the base frame 30 including the central opening 31 by an adhesive (not illustrated). In the present embodiment, since the base film 40 with flexibility is stuck to the base frame 30 with high rigidity, the handling ability of the base member 20 is improved.

The base frame 30 may be omitted and the base member may include only the base film 40. Alternatively, the base film 40 may be omitted and a rigid printed wiring board in which a wiring pattern is formed on a base frame without the opening 31 may be used as the base member.

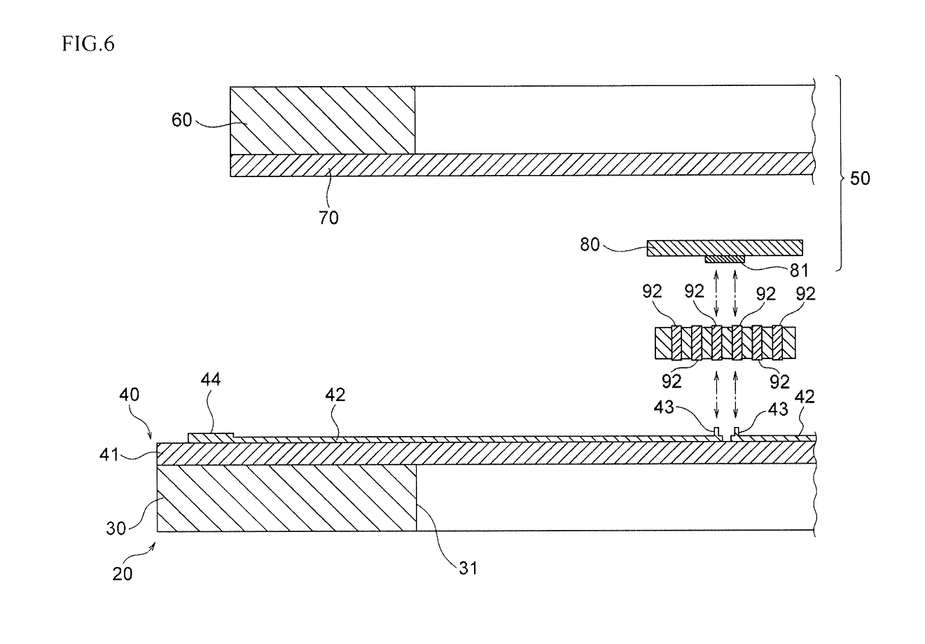

As illustrated in FIG. 6, the base film 40 includes: a film body 41; and a first wiring pattern 42 which is formed on the surface of the film body 41. The film body 41 is, for example, a polyimide film. The first wiring pattern 42 is formed by, for example, etching a copper film laminated on the film body 41. In addition, a cover layer, which is, for example, a polyimide film may be laminated on the film body 41 to protect the first wiring pattern 42, or a so-called multi-layer flexible printed wiring board may be used as the base film.

As illustrated in FIG. 6, a bump 43 is provided at one end of the first wiring pattern 42 in a standing manner so as to come into contact with the lower end of the TSV 92 of the die 90. The bump 43 is made of, for example, copper (Cu) or nickel (Ni) and is formed on the end of the first wiring pattern 42 by, for example, a semi-additive method.

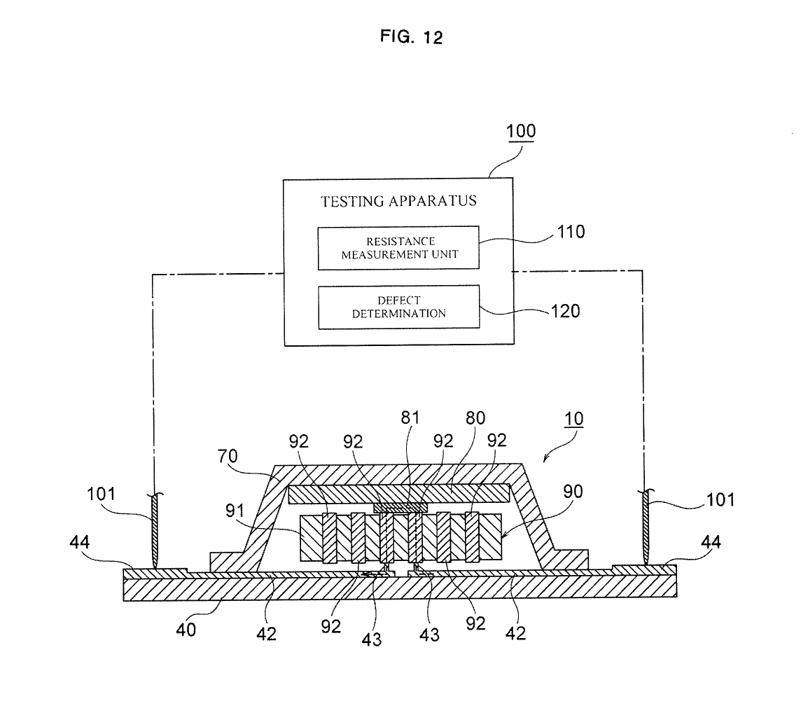

An external terminal 44 is formed at the other end of the first wiring pattern 42. When the electronic circuit formed on the die 90 is tested, a contactor 101 (see FIG. 12) of a testing apparatus 100 electrically contacts the external terminal 44, and the die 90 is electrically connected to the testing apparatus 100 through the test carrier 10.

Note that, the first wiring pattern 42 is not limited to the above-mentioned structure. Although not particularly illustrated in the drawings, for example, a portion of the first wiring pattern 42 may be formed in real time on the surface of the base film 40 by an ink-jet printing method. Alternatively, the entire first wiring pattern 42 may be formed by the ink-jet printing method.

FIG. 6 illustrates only the first wiring pattern 42 corresponding to the innermost TSV 92, in order to facilitate understanding. However, in practice, a plurality of first wiring patterns 42 corresponding to all of the TSVs 92 of the die 90 are formed on the film body 41.

The position of the external terminal 44 is not limited to the above-mentioned position. For example, as illustrated in FIG. 7, the external terminal 44 may be formed on the lower surface of the base film 40. Alternatively, as illustrated in FIG. 8, the external terminal 44 may be formed on the lower surface of the base frame 30. In the example illustrated in FIG. 8, a through hole or a wiring pattern is formed in or on the base frame 30, in addition to the base film 40, so as to electrically connect the bump 43 and the external terminal 44.

As illustrated in FIGS. 3 to 6, the cover member 50 includes a cover frame 60 and a cover film 70. The cover member 50 in the present embodiment corresponds to an example of a second member in the invention. The cover film 70 in the present embodiment corresponds to an example of a first film in the invention.

The cover frame 60 is a rigid plate that has high rigidity (higher rigidity than at least the base film 40) and has an opening 61 formed at the center thereof. The cover frame 60 is made of, for example, glass, a polyimide resin, a polyimide-imide resin, a glass epoxy resin, or ceramics.

The cover film 70 in the present embodiment is a film made of an elastic material that has a lower Young's modulus (lower hardness) than the base film 40 and has a self-adhesive property (stickiness) so as to be more flexible than the base film 40. As an examples of the material forming the cover film 70, silicon rubber or polyurethane is exemplified. The term “self-adhesive property” means a property to adhere to an object without using an adhesive or bond. In the present embodiment, the base member 20 and the cover member 50 are integrated by the self-adhesive property of the cover film 70, instead of the reduced pressure method according to the related art.

As illustrated in FIGS. 3 to 6, the cover member 50 in the present embodiment further includes a wiring film 80 which is provided on the inner surface of the cover film 70. The wiring film 80 is made of a material on which a wire can be formed, such as a polyimide resin, and a second wiring pattern 81 is formed on the lower surface of the wiring film 80. Similarly to the first wiring pattern 42, the second wiring pattern 81 is formed by etching a copper film laminated on the wiring film 80. The second wiring pattern 81 has a pattern shape that electrically connects (short-circuits) two TSVs 92 of the die 90. The second wiring pattern 81 is used to determine whether the TSV 92 is defective (described below). The wiring film 80 in the present embodiment corresponds to an example of a second film in the invention.

Since the cover member 50 has the wiring film 80 in addition to the cover film 70, it is possible to provide the test carrier 10, which uses the self-adhesive property, with the second wiring pattern 81 for determining whether the TSV 90 is defective.

FIG. 6 illustrates only the second wiring pattern 81 corresponding to the innermost TSV 92, in order to facilitate understanding, similarly to the first wiring pattern 42. However, in practice, a plurality of second wiring patterns 81 corresponding to all of the TSVs 92 of the die 90 are formed on the wiring film 80.

In the example illustrated in FIG. 6, no bump is formed at the end of the second wiring pattern 81. However, a bump may be provided in a standing manner at a position of the second wiring pattern 81 which corresponding to the TSV 92 of the die 90, similarly to the bump 43 on the first wiring pattern 42.

Note that, as illustrated in FIGS. 9(a) and 9(b), as the second wiring pattern, a solid pattern 81B with a sufficient size to include all of the TSVs 92 of the die 90 may be formed on the lower surface of the wiring film 80. In this case, when it is determined whether the TSV 92 is defective, it is possible to electrically connect arbitrary TSVs 92 through the second wiring pattern 81B.

In the present embodiment, as illustrated in FIG. 10, the cover film 70 may be made of a material having a lower Young's modulus than the base film 40 and, for example, silicon rubber may be coated on the surface of the film 70 so as to form a self-adhesive layer 71, thereby giving the self-adhesive property to the cover film 70.

In this case, as illustrated in FIG. 10, instead of the self-adhesive layer 71, the second wiring pattern 81 is directly formed in a region of the lower surface of the cover film 70 which faces the die 90. Therefore, the wiring film 80 is not required.

Alternatively, the cover film 70 may be made of a material having a lower Young's modulus than the base film 40 and, for example, silicon rubber may be coated on the upper surface of the base film 40 so as to form a self-adhesive layer 45, thereby giving the self-adhesive property to the base film 40, as illustrated in FIG. 11.

In this case, as illustrated in FIG. 11, instead of the wiring film 80, the second wiring pattern 81 is directly formed on the lower surface of the cover film 70. Therefore, the wiring film 80 is not required.

Note that, in the example illustrated in FIG. 10, the self-adhesive layer 45 may be further formed on the upper surface of the base film 40.

Returning to FIGS. 3 to 6, the cover film 70 is stuck to the entire surface of the cover frame 60 including the central opening 61 by an adhesive (not illustrated). In addition, the wiring film 80 is stuck at a position of the cover film 70 which faces the die 90 by the self-adhesive property of the cover film 70. In the present embodiment, since the flexible cover film 70 is stuck to the cover frame 60 with high rigidity, the handling ability of the cover member 50 is improved. The cover member 50 may include only the cover film 70 and the wiring film 80.

The above-mentioned test carrier 10 is assembled as follows.

That is, first, the cover member 50 is reversed and the die 90 is placed on the wiring film 80. Then, the base member 20 overlaps the cover member 50 such that the die 90 is accommodated in the accommodation space 11 between the base film 40 and the cover film 70. The die 90 is interposed between the base film 40 and the cover film 70.

At that time, in the present embodiment, since the cover film 70 has the self-adhesive property, the base film 40 and the cover film 70 are stuck to each other only by close contact therebetween, and the base member 20 and the cover member 50 are integrated with each other.

In the present embodiment, the cover film 70 is more flexible than the base film 40, and the tension of the cover film 70 is increased by a value corresponding to the thickness of the die 90. The die 90 is pressed against the base film 40 by the tension of the cover film 70. Therefore, it is possible to prevent the positional deviation of the die 90.

When a reduced pressure method (a method of sticking the base film and the cover film in a reduced pressure environment such that the die is interposed therebetween and returning the test carrier to atmospheric pressure) is used instead of the self-adhesive property, the second wiring pattern may be directly formed on the cover film since the cover film does not have the self-adhesive property.

The assembled test carrier 10 is carried to the testing apparatus 100 illustrated in FIG. 12. A contactor 101 of the testing apparatus 100 electrically contacts the external terminal 44 of the test carrier 10, and the electronic circuit of the die 90 is electrically connected to the testing apparatus 100 through the test carrier 10. The electrical characteristics of the electronic circuit of the die 90 are tested.

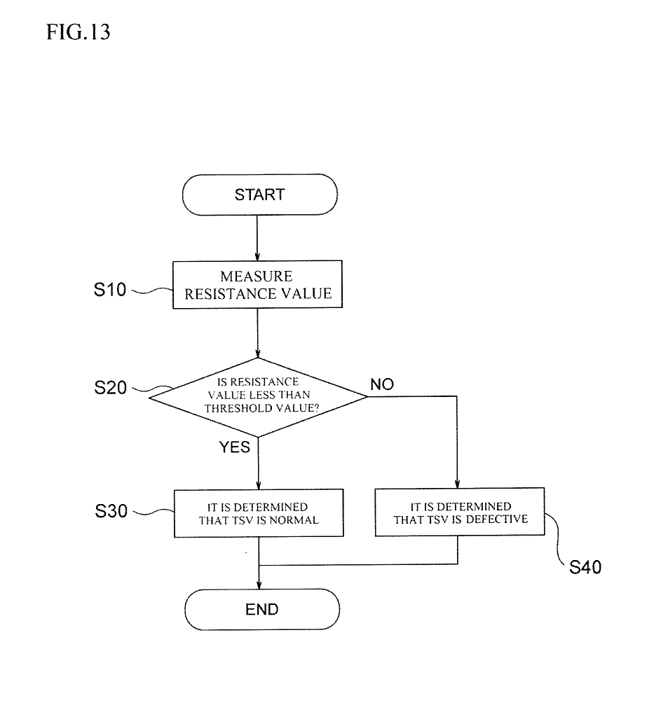

In the present embodiment, before the electronic circuit of the die 90 is tested, it is determined whether the TSV 92 of the die 90 is defective. The process of determining whether the TSV 92 is defective will be described with reference to FIGS. 12 and 13.

FIG. 12 is a block diagram illustrating the structure of the testing apparatus 100 in the present embodiment. FIG. 13 is a flowchart illustrating a TSV defect determination method in the present embodiment.

As illustrated in FIG. 12, the testing apparatus 100 in the present embodiment includes: a resistance measurement unit 110 that measures the resistance value of a conduction path including the TSV 92; and a defect determination unit 120 that determines whether the TSV 92 is defective on the basis of the measurement result of the resistance measurement unit 110, in addition to the function of testing the electrical characteristics of the electric circuit formed in the die 90. In FIG. 12, the base frame 30 and the cover frame 60 are not illustrated.

The testing apparatus 100 determines whether the TSV 92 is defective according to the following procedure.

Specifically, the resistance measurement unit 110 measures the resistance value of a conduction path of the external terminal 44→the first wiring pattern 42→the TSV 92→the second wiring pattern 81→the TSV 9→the first wiring pattern 42→the external terminal 44, in the state that the contactor 101 contacts the external terminal 44 connected to the TSV 92 to be measured (Step S10 in FIG. 13).

Then, the defect determination unit 120 compares the resistance value measured by the resistance measurement unit 110 with a predetermined threshold value (Step S20 in FIG. 13).

When it is determined in Step S20 that the resistance value is less than the predetermined threshold value (YES in Step S20), the defect determination unit 120 determines that all of the TSVs 92 included in the conduction path are “normal” (Step S30 in FIG. 13).

On the other hand, when it is determined in Step S20 that the resistance value is equal to or larger than the predetermined threshold value (NO in Step S20), the defect determination unit 120 that either of the TSVs 92 included in the conduction path is “defective” (Step S40 in FIG. 13). The defective TSV 92 has an inordinately large resistance value due to, for example, the poor filling of a conductive material with a void.

Defects in all of the TSVs 92 are sequentially determined by the above-mentioned method, and the determination results are combined with each other. In this way, it is possible to determine a defect in each of the TSVs 92.

Note that, the above-mentioned embodiment are described for facilitating understanding of the present invention and are not described for limiting the present invention. Therefore, the elements disclosed in the above embodiment include all design modifications and equivalents falling under the technical scope of the present invention.

For example, in the above-described embodiment, the second wiring pattern 81 is connected to the TSV 92. However, the second wiring pattern 81 may be connected to any through electrode which passes through the body of the die.

In the above-described embodiment, the function of determining whether the TSV is defective is added to the testing apparatus 100 which tests the electrical characteristics of the electronic circuit of the die 90. However, the invention is not limited thereto. For example, a TSV defect determination apparatus may be provided independently from the testing apparatus.

### EXPLANATIONS OF LETTERS OR NUMERALS

10 TEST CARRIER
11 ACCOMMODATION SPACE
20 BASE MEMBER
30 BASE FRAME
40 BASE FILM
41 FILM BODY
42 FIRST WIRING PATTERN
43 BUMP
44 EXTERNAL TERMINAL
45 SELF-ADHESIVE LAYER
50 COVER MEMBER
60 COVER FRAME
70 COVER FILM
71 SELF-ADHESIVE LAYER
80 WIRING FILM
81 WIRING PATTERN
90 DIE
92 TSV
100 TESTING APPARATUS
101 CONTACTOR
110 RESISTANCE MEASUREMENT UNIT
120 DEFECT DETERMINATION UNIT

1. A test carrier that temporarily accommodates an electronic device, comprising:
a first wiring pattern that electrically connects an external terminal of the test carrier and one of electrodes which the electronic device has; and
a second wiring pattern that electrically connects at least two of the electrodes.

2. The test carrier according to claim 1, wherein
the electrodes of the electronic device includes a through electrode that passes through a body of the electronic device.

3. The test carrier according to claim 2, further comprising:
a first member that holds the electronic device; and
a second member that overlaps the first member so as to cover the electronic device,
wherein the external terminal and the first wiring pattern are provided in the first member, and
the second wiring pattern is provided in the second member.

4. The test carrier according to claim 3, wherein
the second member includes:
a first film that has a self-adhesive property; and
a second film that is interposed between the first film and the electronic device, and
the second wiring pattern is formed on the second film.

5. The test carrier according to claim 3, wherein
the second member has a surface on which an adhesive layer with a self-adhesive property is partially formed, and
the second wiring pattern is formed in a region of the surface of the second member in which the adhesive layer is not formed.

6. The test carrier according to claim 3, wherein
the first member has a surface on which a layer with a self-adhesive property is formed, and
the second wiring pattern is formed on a surface of the second member.

7. The test carrier according to claim 2, wherein
the second wiring pattern includes a planar solid pattern that electrically connects all of the through electrodes of the electronic device.

8. A defect determination apparatus comprising:
a resistance measurement device configured to measure a resistance value of a conduction path through the external terminal of the test carrier according to claim 2, the conduction path including the through electrode; and
a determination device configured to determine whether the through electrode is defective on the basis of the resistance value.

9. A defect determination method comprising:
electrically connecting at least two through electrodes of an electronic device in series to each other and measuring a resistance value of a conduction path including the through electrodes; and
determining whether the through electrode is defective on the basis of the resistance value.
